(19) United States
(12) Patent Application Publication
(10) Pub. No.: US 2026/0072357 A1
(43) Pub. Date: Mar. 12, 2026

(54) METHOD FOR OPERATING A SOLID-STATE ACTUATOR IN A MICROLITHOGRAPHIC PROJECTION EXPOSURE APPARATUS

(71) Applicant: Carl Zeiss SMT GmbH, Oberkochen (DE)

(72) Inventors: Stefan BAUEREGGER, Dillingen an der Donau (DE); Philip JOERG, Aalen (DE); Markus RAAB, Schillingsfuerst (DE); Thilo POLLAK, Neresheim (DE); Axel WITT, Rheinstetten (DE)

(21) Appl. No.: 19/388,565

(22) Filed: Nov. 13, 2025

Related U.S. Application Data
(63) Continuation of application No. PCT/EP2024/063665, filed on May 17, 2024.

(30) Foreign Application Priority Data
May 22, 2023 (DE) 10 2023 204 749.7

(51) Int. Cl. G03F 7/00; G02B 7/182; G06F 11/07

(52) U.S. Cl. CPC G03F 7/70266; G03F 7/70316; G03F 7/70504; G03F 7/70508; G03F 7/70516; G03F 7/70533; G03F 7/70825; G06F 11/0736; G06F 11/0793; G02B 7/182

(57) ABSTRACT

A method of operating at least one solid-state actuator in a microlithographic projection exposure apparatus comprises the following steps:
requesting a target variable for the at least one solid-state actuator;
ascertaining a control variable using a stored or storable correction model, the correction model comprising a correction function for creep; and
actuating the at least one solid-state actuator using the control variable and switching the at least one solid-state actuator from a switched-off state into a switched-on state by feeding energy from an energy source.

### CROSS-REFERENCE TO RELATED APPLICATIONS

The present application is a continuation of, and claims benefit under 35 USC 120 to, international application No. PCT/EP2024/063665, filed May 17, 2024, which claims benefit under 35 USC 119 of German Application No. 10 2023 204 749.7, filed May 22, 2023. The entire disclosure of each of these applications is incorporated by reference herein.

### FIELD

The disclosure relates to a method for operating, for example switching on, at least one solid-state actuator in a microlithographic projection exposure apparatus.

### BACKGROUND

Projection exposure apparatuses are used to produce extremely fine structures, for example on semiconductor components or other microstructured component parts. The operating principle of the apparatuses is based on the production of extremely fine structures down to the order of nanometres by way of generally reducing imaging of structures on a mask, a so-called reticle, on an element to be structured, a so-called wafer, that is provided with photosensitive material. The minimum dimensions of the structures produced are, in general, directly dependent on the wavelength of the light used. The light is shaped for the optimum illumination of the reticle in an illumination optics unit. Recently, light sources having an emission wavelength in the order of a few nanometres, for example between 1 nm and 120 nm, such as on the order of 13.5 nm, have increasingly been used. The described wavelength range is also referred to as the EUV range.

Apart from with the use of systems which operate in the EUV range, the microstructured component parts are also produced using commercially established DUV systems, which have a wavelength of between 100 nm and 300 nm, for example 193 nm. With the general desire to be able to produce smaller and smaller structures, the optical correction in the systems has likewise increased further. To reduce aberrations, the optical elements of the microlithographic projection exposure apparatus, i.e. the lens elements or the mirrors for example, are adjusted or positioned, or their active surface is deformed, via actuators. In this case, the actuators can be formed as solid-state actuators, wherein solid-state actuators within the meaning of the present disclosure are electrostrictive or piezoelectric actuators. The solid-state actuators are secured to the optical element, for example to the back side thereof, wherein the actuators are able to actuate in a manner normal to the surface or parallel to the surface. The position or the profile of the mirror can be set in a targeted manner by actuating each individual actuator.

Deviations between the predetermined or desired strain (target variable) and the actual strain can arise, inter alia on account of hysteresis and creep effects, when the solid-state actuators are controlled. According to a current theory, these transient and non-reversible processes are based on domain-like flipping mechanisms at the molecular level of dipole moments. An issue with creep for example is that the time constant is relatively long, and so the equilibrium state of the solid-state actuator is either not reached at all or only reached a relatively long time after the operating point has been set or after the solid-state actuator has been switched on. This can lead to a delay in the operation of a microlithographic projection exposure apparatus, as it is desirable to wait until the system is at least approximately in equilibrium, i.e. the desired accuracy for the system is satisfied. In this context, the term creep hereinafter denotes anything that is linked to the processes mentioned below:
logarithmic creep
Cole-Cole behaviour
Havriliak-Negami relaxation
Debeye relaxation
Kohlrausch-William-Watts relaxation
stretched exponential function.

### SUMMARY

The present disclosure seeks to overcome or at least reduce certain disadvantages.

A method according to the disclosure for operating, for example switching on, at least one solid-state actuator in a microlithographic projection exposure apparatus comprises the following steps:
requesting a target variable for the at least one solid-state actuator;
ascertaining a control variable from the target variable using a stored or storable correction model, the correction model comprising at least one correction function for creep; and
actuating the at least one solid-state actuator using the control variable and switching the at least one solid-state actuator from a switched-off state into a switched-on state by feeding energy from an energy source.

A method according to the disclosure can help allow the effect of creep on the actuator behaviour of the at least one solid-state actuator when the latter is switched on to be corrected or at least reduced using a feedforward approach. To set a desired state, for example the deflection of a solid-state actuator (the target variable), a control variable can be ascertained on the basis of a correction model that is stored or storable in a memory of a controller. In this case, the correction model can comprise at least one correction function for creep. Thus, the ascertainment of the control variable can consider firstly the strain response of the at least one solid-state actuator to a change in the electric field or a change in energy and secondly non-reversible effects such as creep. As a result, this can help shorten the waiting time until the solid-state actuator is in equilibrium and the desired accuracy for the system can be satisfied when the solid-state actuator is switched on, i.e. when the solid-state actuator is set to a first operating point. In this case, actuation may be implemented by way of current or charge, voltage, temperature, stress or strain. The energy source may be a voltage source or a current source or a heating element.

Furthermore, it can be desirable for the at least one solid-state actuator, and optionally every solid-state actuator in the microlithographic projection exposure apparatus, to be supplied by an external energy source that is separate from the energy source of the projection exposure apparatus. In this case, it can be desirable for the at least one solid-state actuator to be operated in continuous operation, in such a way that the energy supply by the separate energy source is provided continuously and independently of the energy supply of the microlithographic projection exposure apparatus. In this case, the separate energy source may be a current source, a voltage source, a heating element, a source of charge, etc. Consequently, the at least one solid-state actuator can be operated in continuous operation such that the solid-state actuator cannot be separated from the energy supply. This can help allow a further reduction in the creep effect since the solid-state actuators do not leave the equilibrium state or only leave the latter to a reduced extent.

Within the scope of the disclosure, it can be desirable for the correction function for creep at least to comprise or approximate the following function:

$${ε}_{dyn} = {ε}_{0} γ {log}_{a} ( 1 + \frac{t}{{t}_{0}} ) ,$$

where ε_{dyn} is the strain of the at least one solid-state actuator caused by creep, ε₀ is the step height at time to, a is the base of the logarithm, t is the time and γ is a factor of proportionality. For example, the aforementioned function may be approximated by a sum of linear time-invariant transfer functions. In this case, the base a of the logarithmic function may be 10 or a base that deviates from 10, for example e, i.e. the natural logarithm.

Furthermore, it can be desirable for the mathematical description of the creep to be implemented by an approximation, wherein the correction function comprises a sum of logarithmic functions or is approximated by a sum of linear time-invariant transfer functions. The individual logarithmic summands may also have different bases.

To help enable an even more accurate control of the at least one solid-state actuator, it can be desirable for, in addition to the correction function for creep, the correction model to take account of a correction factor for hysteresis as a further transient non-reversible effect. In this context, the correction functions can be added to one another. To describe the hysteresis, it is possible to use the Bouc Wen model, the Prandtl-Ishlinskii model or the Preisach model, among others, as model. The correction function of the hysteresis may be or comprise a sum of linear time-invariant transfer functions, i.e. for example a superposed PT1 function, or a superposed log function or a fractional differential equation.

Optical elements usually comprise a plurality of actuators. Moreover, different optical elements in a microlithographic projection exposure apparatus may comprise actuators from different manufacturers or actuators whose ages differ. Furthermore, it may also be expedient to jointly actuate a group of solid-state actuators and divide the solid-state actuators into groups, wherein the solid-state actuators within a group are actuated jointly, while different groups are actuated separately from one another. In this context, it can be desirable for a method to comprise the following additional steps:
characterizing the at least one solid-state actuator according to at least one characterization parameter;
classifying the solid-state actuators of a characterization parameter into at least two subgroups that differ in terms of a subparameter of the characterization parameter;
storing separate correction models for at least two subgroups; and
within the scope of ascertaining the control variable of a solid-state actuator, applying the stored correction model associated with the subgroup of the solid-state actuator.

In other words, the solid-state actuators can be characterized according to at least one characterization parameter. In this case, it can be desirable for the characterization parameters to be selected from the following list: manufacturer, material, association with an actuation group or age. The solid-state actuators of a characterization parameter, i.e. manufacturer for example, can be classified into subgroups that differ in terms of a subparameter—for example manufacturer A and manufacturer B. Separate correction functions, for example separate correction models, can be stored in a memory of a controller for at least two of these subgroups and optionally for each of these subgroups. Within the scope of ascertaining the control variable from the target variable when controlling a solid-state actuator, the correction model stored in the memory that is associated with the solid-state actuator, i.e. associated with the subgroup into which the solid-state actuator has been classified, can be applied. Different age classes may be subparameters for the age characterization parameter. Analogously, different material groups may serve as subparameters for the material characterization parameter. Furthermore, the different actuation groups may form the subparameter for the actuation group characterization parameter. This can help allow manufacturer-specific, product-specific, ageing-specific and/or material-specific effects on the creep and/or on the dynamics of the strain to be taken into account. Moreover, it can be desirable for the characterization steps to be performed repeatedly, i.e. there is at least one, and optionally more than one, re-characterization of the actuators. This can be desirable in view of progressive ageing, material wear, etc. In this context, the above-described characterization steps may be repeated at predetermined or predeterminable time intervals, for example in regular or irregular fashion.

Moreover, in a method that can be implemented relatively easily, it can be desirable for the parameters of the correction model, i.e. E., Y and to for example, to be predetermined, i.e. defined.

However, it can be desirable for the parameters of the correction model to be calibrated and the correction function or the correction model to be stored. In this context, the parameters may also be variable or changeable.

However, it can be desirable for the parameters of the correction model, for example ε₀, γ and t₀, to be calibrated or recalibrated at predetermined time intervals, for example at regular time intervals, and stored in a memory of a control unit as new correction function or new correction model. This can help for example to take account of the ageing of the solid-state actuators.

Furthermore, it can be desirable within the scope of the disclosure for the method additionally to comprise the steps of:
requesting a first target variable when changing from a first operating point of the at least one solid-state actuator to a second operating point;
ascertaining a control variable using a stored correction model, the correction model comprising the correction function for creep; and
actuating the solid-state actuator using the control variable.

In other words, the above-described method may also be applied when there is a change in operating point of a solid-state actuator, and this can help reduce the waiting time until the solid-state actuator is in equilibrium or meets the demands on the accuracy of the controller.

The scope of the disclosure can provide for the solid-state actuator to be in the form of an electrostrictive or piezoelectric actuator.

Furthermore, it can be desirable for the actuator positions, i.e. to adjust, an optical element or to deform the active surface of the latter.

In this case, the optical component can be in the form of a mirror, for example in the form of an adaptive mirror. In an alternative, the optical element may also be in the form of a lens element.

In an alternative, the creep effect may also be corrected by a feedback approach rather than a feedforward approach. That is to say, the effect of creep and/or hysteresis in a solid-state actuator may initially be measured and then be corrected accordingly via a controller, i.e. controlled with respect to the measured variable. In this case, the measurement may be implemented directly, i.e. by way of the strain of the at least one solid-state actuator, or indirectly via a voltage measurement or a current measurement or an impedance measurement or a charge measurement. Alternatively, the measurement may also be implemented centrally by way of a wavefront measurement. In an alternative, there may also be a dedicated measurement for a solid-state actuator or a group of solid-state actuators. The measured variable may be mapped onto the control variable as desired, for example using a lookup table or equations, etc. Moreover, mapping may be implemented directly or by way of controller structures. Moreover, in a method that can be implemented relatively easily, it can be desirable for the parameters for the control to be predetermined, i.e. defined. However, it can be desirable for the parameters for the control to be calibrated and for example recalibrated. In this context, the parameters may also be variable or changeable. However, it can be desirable for the parameters of the control to be calibrated or recalibrated at predetermined time intervals, for example at regular time intervals, and stored in a memory of a control unit as new correction function or new correction model. This helps for example to take account of the ageing of the solid-state actuators.

Furthermore, it can be desirable for the correction model (the feedforward approach) to be combined with the above-described feedback solution. That is to say, the parameter measurement and the correction model prediction are combined with each other, for example using a weighted combination. In this context, the weights may be unchangeable (defined), calibrated or recalibrated at regular or irregular time intervals. Hence creep is both measured and also simulated by way of the correction model.

Further features, properties and aspects of the present disclosure are described in more detail below on the basis of embodiment variants and with reference to the appended figures. In this respect, all the features described above and below can be implemented both individually and in any desired combination. The embodiment variants described below are merely examples which, however, do not limit the subject matter of the disclosure.

### BRIEF DESCRIPTION OF THE DRAWINGS

In the figures:

FIG. 1A shows a schematic illustration of a microlithographic projection exposure apparatus designed for operation in the EUV;

FIG. 1B shows a schematic illustration of a microlithographic projection exposure apparatus designed for operation in the DUV;

FIG. 2 shows a flowchart regarding the sequence of a method for operating a microlithographic projection exposure apparatus; and

FIG. 3 shows a further flowchart regarding the sequence of a method for operating a microlithographic projection exposure apparatus.

### DETAILED DESCRIPTION

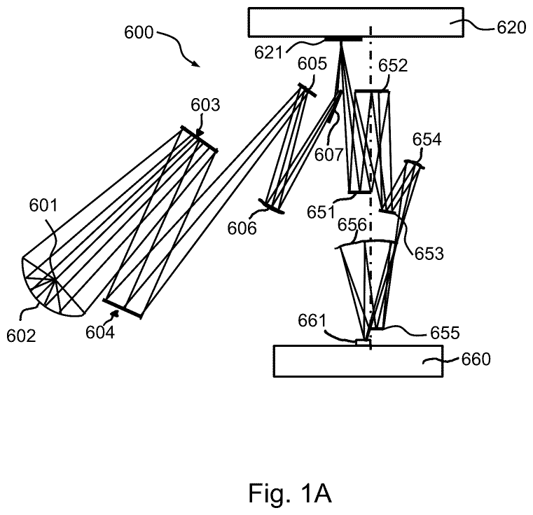

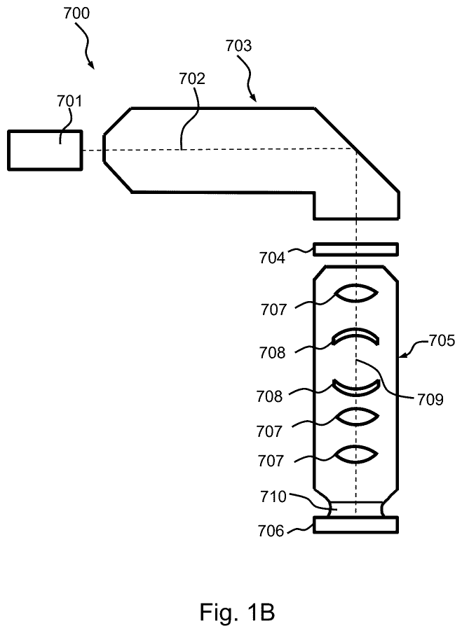

FIG. 1A shows a schematic illustration of an exemplary projection exposure apparatus 600 which is designed for operation in the EUV and in which the present disclosure can be realized.

According to FIG. 1A, an illumination module in a projection exposure apparatus 600 designed for EUV comprises a field facet mirror 603 and a pupil facet mirror 604. The light from a light source unit comprising a plasma light source 601 and a collector mirror 602 is directed to the field facet mirror 603. A first telescope mirror 605 and a second telescope mirror 606 are arranged downstream of the pupil facet mirror 604 in the light path. A deflection mirror 607 is arranged downstream in the light path and directs the radiation that is incident thereon onto an object field in the object plane of a projection lens comprising six mirrors 651-656. At the location of the object field, a reflective structure-bearing mask 621 is arranged on a mask stage 620 and with the aid of the projection lens is imaged into an image plane, in which a substrate 661 coated with a light-sensitive layer (photoresist) is situated on a wafer stage 660. One or more of the mirrors of the projection exposure apparatus 600 designed for EUV may be formed as the adaptive optical element 100 according to the disclosure.

The disclosure may likewise be used in a DUV apparatus, as illustrated in FIG. 1B. A DUV apparatus is set up in principle like the above-described EUV apparatus from FIG. 1A, wherein mirrors and lens elements can be used as optical elements in a DUV apparatus, and the light source of a DUV apparatus emits used radiation in a wavelength range of 100 nm to 300 nm.

The DUV lithography apparatus 700 illustrated in FIG. 1B comprises a DUV light source 701. For example, an ArF excimer laser that emits radiation 702 in the DUV range at for example 193 nm may be provided as the DUV light source 701. A beam shaping and illumination system 703 guides the DUV radiation 702 onto a photomask 704. The photomask 704 is embodied as a transmissive optical element and may be arranged outside the systems 703. The photomask 704 comprises a structure that is imaged onto a wafer 706 or the like in a reduced fashion via the projection system 705. The projection system 705 comprises multiple lens elements 707 and/or mirrors 708 for imaging the photomask 704 onto the wafer 706. In this case, individual lens elements 707 and/or mirrors 708 of the projection system 705 may be arranged symmetrically with respect to the optical axis 709 of the projection system 705. It should be noted that the number of lens elements 707 and mirrors 708 of the DUV lithography apparatus 700 is not restricted to the number illustrated. A greater or lesser number of lens elements 707 and/or mirrors 708 may also be provided. For example, the beam shaping and illumination system 703 of the DUV lithography apparatus 700 comprises multiple lens elements 707 and/or mirrors 708. Furthermore, the mirrors are generally curved on their front side for beam shaping purposes. An air gap 710 between the last lens element 707 and the wafer 706 may be replaced by a liquid medium having a refractive index of >1. The liquid medium may be high-purity water, for example. Such a construction is also referred to as immersion lithography and has an increased photolithographic resolution.

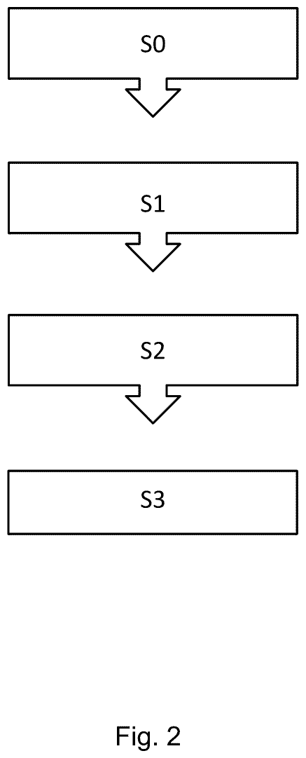

FIG. 2 shows a flowchart of a method for operating, for example switching on, at least one solid-state actuator in a microlithographic projection exposure apparatus 600, 700. Initially, a correction model, which comprises at least one correction function for creep, is stored in a memory of a controller (step SO). In this context, the parameters may be defined, or the parameters of the correction function or of the correction model may have been ascertained in advance using a calibration on the at least one solid-state actuator. To switch on the solid-state actuator, the controller can initially request a target variable for the at least one solid-state actuator (step S1) and ascertain a control variable using the correction model that is stored or storable in the memory, wherein the correction model comprises a correction function for creep. The solid-state actuator is then actuated via the control variable and switched from a switched-off state into a switched-on state by supplying energy from an energy source (step S3). Thus, when ascertaining the control variable from the target variable via the controller, an equilibrium strain response of the solid-state actuator to an energy supply and the correction model with at least one correction function for creep is taken into account. This allows the effect of creep on the strain behaviour of the at least one solid-state actuator when the latter is switched on to be corrected using a feedforward approach. This significantly shortens the waiting time until the solid-state actuator and hence the projection exposure apparatus 600, 700 is in equilibrium at the set operating point, and the desired accuracy for the system is achieved. In this case, actuation may be implemented by way of current or charge, voltage, temperature, stress or strain.

Furthermore, the at least one solid-state actuator, optionally every solid-state actuator in the microlithographic projection exposure apparatus 600, 700, may optionally be supplied by an external energy source that is separate from the energy source of the projection exposure apparatus. In this case, it can be desirable for the at least one solid-state actuator to be operated in continuous operation, in such a way that the energy supply by the separate energy source is provided continuously and independently of the energy supply of the microlithographic projection exposure apparatus 600, 700. In this case, the separate energy source may be a current source, a voltage source, a heating element, a source of charge, etc. Consequently, the at least one solid-state actuator can be operated in continuous operation such that the solid-state actuator cannot be separated from the energy supply. This allows a further reduction in the creep effect since the solid-state actuators do not leave the equilibrium state or only leave the latter to a reduced extent.

The correction function for creep comprises or approximates optionally at least the following function:

$${ε}_{dyn} = {ε}_{0} γ {log}_{a} ( 1 + \frac{t}{{t}_{0}} ) ,$$

where ε_{dyn} is the strain of the at least one solid-state actuator caused by creep, ε₀ is the step height at time t₀, a is the base of the logarithmic function, t is the time and γ is a factor of proportionality. In this case, the base a of the logarithmic function may be 10 or a base that deviates from 10, for example e, i.e. the natural logarithm.

Furthermore, the parameters of the correction model, i.e. of the correction function for example, for example ε₀, γ and t₀, may be calibrated or recalibrated at predetermined time intervals, for example at regular time intervals, and stored in the memory of the controller as new correction function or new correction model. This helps for example to take account of the ageing of the solid-state actuators in the correction of creep effects.

Furthermore, it can be desirable for the mathematical description of the creep to be implemented by an approximation, wherein the correction function for example comprises a sum of logarithmic functions or is approximated by a sum of linear time-invariant transfer functions. The individual logarithmic summands may also have different bases.

To enable an even more accurate control of the at least one solid-state actuator, it can be desirable for, in addition to the correction function for creep, the correction model additionally to comprise a correction factor for hysteresis. In this context, the two correction functions can be added to each other. To describe the hysteresis, it is for example possible to use the Bouc Wen model, the Prandtl-Ishlinskii model or the Preisach model as model. The correction function of the hysteresis may be or comprise a sum of linear time-invariant transfer functions, i.e. for example a superposed PT1 function, or a superposed log function or a fractional differential equation.

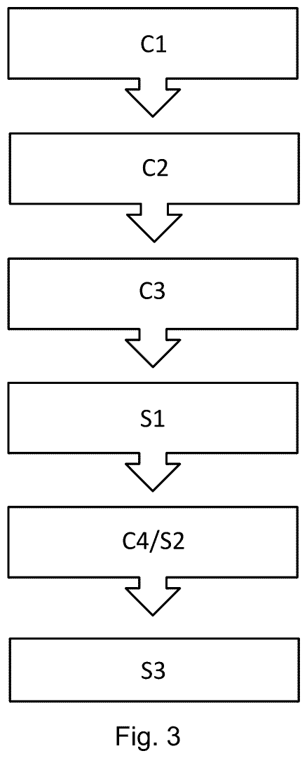

Optical elements usually comprise a plurality of actuators. Moreover, different optical elements in a microlithographic projection exposure apparatus may comprise actuators from different manufacturers with creep behaviours that differ from one another. The age of the actuators may also differ. Furthermore, it may also be expedient to combine the solid-state actuators in groups, wherein the solid-state actuators within a group are actuated jointly, while different groups are actuated separately from one another. In this context, it can be desirable for the scope of the method to include characterizing each solid-state actuator or at least some of the solid-state actuators according to at least one characterization parameter (step C1). This is illustrated in the flowchart of FIG. 3. This may be implemented simultaneously with or before or after step SO or may comprise step SO In this case, it can be desirable for the characterization parameters to be selected from the following list: manufacturer, material, association with an actuation group or age. The solid-state actuators of a characterization parameter, i.e. manufacturer for example, are classified into subgroups that differ in terms of a subparameter—for example manufacturer A and manufacturer B (step C2). Separate correction functions, for example separate correction models, are stored in a memory of a controller for at least two of these subgroups and optionally for each of these subgroups (step C3). When controlling a solid-state actuator, a target variable is requested once again (step S1). When ascertaining the control variable from the target variable, the correction model stored in the memory that is associated with the solid-state actuator, i.e. associated with the subgroup into which the solid-state actuator has been classified, is applied in the present case (step C4/S2). Different age classes may be subparameters for the age characterization parameter. Analogously, different material groups may serve as subparameters for the material characterization parameter. Furthermore, the different actuation groups may form the subparameter for the actuation group characterization parameter. Subsequently, the solid-state actuator is then actuated via the control variable and switched from a switched-off state into a switched-on state by supplying energy from an energy source (step S3). This allows manufacturer-specific, product-specific, ageing-specific and/or material-specific effects on the creep and/or on the dynamics of the strain to be taken into account.

The solid-state actuator is in the form of an electrostrictive or piezoelectric actuator, and the solid-state actuator is configured to position, i.e. adjust, an optical element of the projection exposure apparatus 600, 700, i.e. a mirror or a lens element for example, or to deform the active surface of the optical element.

The above-described method may also be applied when the operating point of the solid-state actuator is changed, in addition to the application within the switch-on procedure. In this case, a further target variable is requested from the controller when changing from a first operating point of the at least one solid-state actuator to a second operating point. The control variable is ascertained using the stored correction model, wherein the correction model comprises the correction function for creep, and the solid-state actuator is actuated using the control variable.

### LIST OF REFERENCE SIGNS

600 Projection exposure apparatus
601 Plasma light source
602 Collector mirror
603 Field facet mirror
604 Pupil facet mirror
605 First telescope mirror
606 Second telescope mirror
607 Deflection mirror
620 Mask stage
621 Mask
651 Mirror (projection lens)
652 Mirror (projection lens)
653 Mirror (projection lens)
654 Mirror (projection lens)
655 Mirror (projection lens)
656 Mirror (projection lens)
660 Wafer stage
661 Coated substrate
700 DUV lithography apparatus
701 DUV light source
702 DUV radiation/beam path
703 Beam shaping and illumination system (DUV)
704 Photomask
705 Projection system
706 Wafer
707 Lens element
708 Mirror
709 Optical axis

What is claimed is:

1. A method of operating a solid-state actuator in a microlithographic projection exposure apparatus, the method comprising:
requesting a target variable for the solid-state actuator;
ascertaining a control variable using a stored or storable correction model, the correction model comprising a correction function for creep; and
actuating the solid-state actuator using the control variable and switching the at least one solid-state actuator from a switched-off state into a switched-on state by providing energy to the solid-state actuator.

2. The method of claim 1, wherein the microlithographic projection exposure apparatus comprises an energy source, and the energy is provided to the solid-state actuator from an external energy source that is separate from the energy source of the microlithographic projection exposure apparatus.

3. The method of claim 1, wherein the correction function for creep at least comprises or approximates the following function:
$${ε}_{dyn} = {ε}_{0} γ {log}_{a} ( 1 + \frac{t}{{t}_{0}} ) ,$$
where ε_{dyn} is a strain of the solid-state actuator caused by creep, a is a base of the logarithm, ε₀ is a step height at time t₀, t is the time and γ is a factor of proportionality.

4. The method of claim 1, wherein the correction function comprises a sum of logarithmic functions or is approximated by a sum of linear time-invariant transfer functions.

5. The method of claim 1, wherein the correction model takes account of a correction factor for hysteresis.

6. The method of claim 1, further comprising:
characterizing the solid-state actuator according to at least one characterization parameter;
classifying the solid-state actuators of a characterization parameter into at least two subgroups that differ in terms of a subparameter of the characterization parameter; and
storing separate correction models for the at least two subgroups,
wherein ascertaining the control variable of a solid-state actuator comprises applying the stored correction model associated with the subgroup of the solid-state actuator.

7. The method of claim 6, wherein the characterization parameter is selected from the group consisting of a manufacturer, a material, an association with an actuation group, and an association with an actuator age.

8. The method of claim 1, wherein parameters of the correction model are predetermined.

9. The method of claim 1, wherein parameters of the correction model are calibrated.

10. The method of claim 9, wherein parameters of the correction model are recalibrated at predetermined time intervals.

11. The method of claim 1, further comprising:
requesting a further target variable when changing from a first operating point of the solid-state actuator to a second operating point;
ascertaining a control variable using a stored correction model, the correction model comprising the correction function for creep; and
actuating the solid-state actuator using the ascertained control variable.

12. The method of claim 1, wherein the solid-state actuator comprises an electrostrictive or a piezoelectric actuator.

13. The method of claim 1, further comprising using the solid-state actuator to position or deform an optical element.

14. The method of claim 13, wherein the optical component comprises a mirror.

15. The method of claim 1, wherein:
the microlithographic projection exposure apparatus comprises an energy source;
the energy is provided to the solid-state actuator from an external energy source that is separate from the energy source of the microlithographic projection exposure apparatus; and
the correction function for creep at least comprises or approximates the following function:
$${ε}_{dyn} = {ε}_{0} γ {log}_{a} ( 1 + \frac{t}{{t}_{0}} ) ,$$
where ε_{dyn} is a strain of the solid-state actuator caused by creep, a is a base of the logarithm, ε₀ is a step height at time t₀, t is the time and γ is a factor of proportionality.

16. The method of claim 1, wherein:
the microlithographic projection exposure apparatus comprises an energy source;
the energy is provided to the solid-state actuator from an external energy source that is separate from the energy source of the microlithographic projection exposure apparatus; and
the correction function comprises a sum of logarithmic functions or is approximated by a sum of linear time-invariant transfer functions.

17. The method of claim 1, wherein:
the microlithographic projection exposure apparatus comprises an energy source;
the energy is provided to the solid-state actuator from an external energy source that is separate from the energy source of the microlithographic projection exposure apparatus; and
the correction model takes account of a correction factor for hysteresis.

18. The method of claim 1, further comprising:
characterizing the solid-state actuator according to at least one characterization parameter;
classifying the solid-state actuators of a characterization parameter into at least two subgroups that differ in terms of a subparameter of the characterization parameter; and
storing separate correction models for the at least two subgroups,
wherein:
ascertaining the control variable of a solid-state actuator comprises applying the stored correction model associated with the subgroup of the solid-state actuator;
the microlithographic projection exposure apparatus comprises an energy source; and
the energy is provided to the solid-state actuator from an external energy source that is separate from the energy source of the microlithographic projection exposure apparatus.

19. The method of claim 1, wherein:
the microlithographic projection exposure apparatus comprises an energy source;
the energy is provided to the solid-state actuator from an external energy source that is separate from the energy source of the microlithographic projection exposure apparatus; and
parameters of the correction model are predetermined, and/or parameters of the correction model are calibrated.

20. A method of operating a solid-state actuator in a microlithographic projection exposure apparatus, the method comprising:
requesting a target variable for the solid-state actuator;
ascertaining a control variable using a stored or storable correction model, the correction model comprising a correction function for creep; and
actuating the solid-state actuator using the control variable via a feed forward approach and switching the solid-state actuator from a switched-off state into a switched-on state by feeding energy to the solid-state actuator.
